(19) United States
(12) Patent Application Publication
(10) Pub. No.: US 2009/0211628 A1
(43) Pub. Date: Aug. 27, 2009

(54) Rear contact solar cell and method for making same

(75) Inventors: Peter Engelhart, Hameln (DE); Andreas Teppe, Alzenau (DE); Rainer Grischke, Hildesheim (DE); Robert Wade, Leipzig (DE)

Correspondence Address: LERNER, DAVID, LITTENBERG,;KRUMHOLZ & MENTLIK, 600 SOUTH AVENUE WEST, WESTFIELD, NJ, 07090, US

(73) Assignee: Institut Fur Solarenergieforschung GmbH, Emmerthal (DE)

(21) Appl. No.: 11/918,271

(22) PCT Filed: Apr. 11, 2006
(86) PCT No.: PCT/EP2006/003331

§ 371 Date: Apr. 17, 2009

(30) Foreign Application Priority Data
Apr. 16, 2005 (DE) 10 2005 017 767.0
Aug. 29, 2005 (DE) 10 2005 040 871.0

(51) Int. Cl. H01L 31/0224; H01L 21/28

(52) U.S. Cl. 136/256; 438/57; 257/E31.124; 257/E21.158

(57) ABSTRACT

The invention concerns a solar cell (1) and a method for making same, said solar cell (1) comprising on its rear surface (3) both the emission contact (43) and the base contact (45), those two contacts (43, 45) being electrically isolated from each other by flanks (5) whereof the metal coating has been removed. The emitting zones (4) of the rear surface (3) of the cell are connected by channels to the transmitter (9) of the front face (8) of the cell. The emitting zones (4) of the rear surface (3) of the cell and the channels (7) consist of a laser. The metal coating of the side walls is removed by selective etching, said metal coating being removed only in the zone of the flanks (5) where the etching barrier layer (11) is insufficient.

### FIELD OF THE INVENTION

The present invention relates to a solar cell, in which both an emitter contact and a base contact are arranged on a rear surface of a semiconductor substrate, and to a method for making said solar cell.

### BACKGROUND TO THE INVENTION

Solar cells are used to convert light into electrical energy. In this process, in a semiconductor substrate, charge carrier pairs that have been generated by light are separated by means of a pn-junction, whereupon they are fed, by way of the emitter contact and the base contact, to an electrical circuit comprising a consumer.

### PRIOR ART

In conventional solar cells the emitter contact is usually arranged on the front, i.e. on the face pointing towards the light source, of the semiconductor substrate. However, e.g. in JP 5-75149 A, DE 41 43 083 and DE 101 42 481, solar cells have been proposed in which both the base contact and the emitter contact are arranged on the substrate rear. On the one hand in this arrangement shading of the front as a result of the contacts is avoided, which results in improved efficiency and in a more pleasing appearance of the solar cell, and on the other hand such solar cells can more easily be connected in series because the rear of a cell does not have to be contacted to the front of an adjacent cell.

In other words, a solar cell without frontside metallisation offers several advantages: the front of the solar cell is not shaded by contacts, so that the incident radiation energy can generate charge carriers in the semiconductor substrate without there being any restrictions; and, furthermore, these cells can be more easily connected to form modules, and the cells also have a more pleasing appearance.

However, conventional so-called rear contact solar cells are associated with several disadvantages. In most cases their production processes are expensive. Numerous methods necessitate several masking steps, several etching steps and/or several vapour depositing steps in order to form the base contact so that it is electrically separated from the emitter contact on the rear of the semiconductor substrate. Moreover, conventional rear contact solar cells are often plagued by local short-circuits, e.g. as a result of inversion layers between the base region and the emitter region, or as a result of inadequate electrical insulation between the emitter contact and the base contact, which leads to reduced efficiency of the solar cell.

A solar cell without frontside metallisation is, for example, known from R. M. Swanson, “Point Contact Silicon Solar Cells”, Electric Power Research Institute, rep. AP-2859, May 1983. This cell concept has been continually improved (R. A. Sinton, “Bilevel contact solar cells”, U.S. Pat. No. 5,053,083, 1991). A simplified version of this point-contact solar cell is produced by SunPower Corporation in a pilot line (K. R. McIntosh, M. J. Cudzinovic, D- D Smith, W- P. Mulligan, and R. M. Swanson “The choice of silicon wafer for the production of low-cost rear-contact solar cells” 3rd World Conference of PV Energy Conversion, Osaka 2003 in press).

To produce the above-mentioned solar cells, in several masking steps differently-doped regions are created side-by-side and are metallised or contacted by applying a metal structure, which in part is a multilayer metal structure.

The above is associated with a disadvantage in that these methods require several adjusting masking steps and are therefore expensive or elaborate.

From the patent specification JP 5-75149A a solar cell without frontside metallisation is known, which solar cell comprises raised and depressed regions on its rear. This solar cell, too, can only be produced in several masking- and etching steps.

Patent specification DE 41 43 083 describes a solar cell without frontside metallisation, in which solar cell adjusting masking steps are not mandatory. However, the efficiency of this cell is poor, because the inversion layer connects both contact systems, which results in low parallel resistance (shunt resistance) and thus a low filling factor.

Patent specification DE 101 42 481 describes a solar cell with base contact and emitter contact arranged on the rear. This solar cell, too, has a rear structure; however, the contacts are located on the flanks of the raised regions. This requires two vacuum vapour-depositing steps to produce the contacts. Furthermore, the production of a local emitter is technologically demanding in the case of this cell.

Rear-contact solar cells are associated with a particular difficulty in that the production of the rear contacts is expensive or elaborate, with electrical shortcuts during production having to be avoided at all cost.

### OBJECT OF THE INVENTION

It is an object of the present invention to avoid or at least minimise the above-mentioned problems, and to provide a solar cell and a production method for a solar cell that achieves high efficiency and is simple to produce.

According to the invention this object is met by a production method and a solar cell with the characteristics of the independent claims. Advantageous embodiments and improvements of the invention are stated in the dependent claims.

In particular, this invention solves in a simple manner the problem of producing the two rear contact systems and their proper electrical separation, and describes a solar cell that consequently is easy to produce. Irrespective of the type of electrical separation of the two rear contact systems the solar cell itself can be designed as an emitter-wrap-through (EWT) solar cell.

### DESCRIPTION OF THE INVENTION

According to a first aspect of the invention, a method for producing a solar cell is stated, which method involves the following steps: providing a semiconductor substrate with a substrate front and a substrate rear; forming a first and a second region on the substrate rear, wherein in each case the regions are essentially parallel in relation to the substrate front, and forming an inclined flank that separates the first region from the second region; depositing a metal layer at least on partial regions of the substrate rear; depositing an etching barrier layer at least on partial regions of the first metal layer, wherein the etching barrier layer is essentially resistant to an etchant that etches the metal layer; etching the metal layer at least in partial regions, wherein the metal layer on the inclined flank is essentially removed.

A silicon wafer can be used as a semiconductor substrate. The method is, in particular, suited for use with silicon wafers of lesser quality, for example of multicrystalline silicon or Cz silicon with a minority charge carrier diffusion-length that is shorter than the thickness of the wafer.

The terms “first region” and “second region” on the substrate rear refer to those regions that in the completed solar cell define the emitter region and the base region of the solar cell and that comprise different doping of the n-type or of the p-type. Both regions are preferably flat. In order to achieve even distribution of the two regions across the substrate rear, the two regions can be interdigitated, i.e. nestled in a comb-like manner. A main direction of extension of the regions is essentially parallel in relation to the substrate front. This also applies if individual partial regions are not flat, e.g. if the individual fingers of a comb-like structure are U-shaped in cross section.

According to the invention, at least one flank separates the first and the second region from each other. In this document, the term “flank” refers to an area which in relation to the substrate front and thus also to the planes of the first and the second region is at an angle of at least 60°. Preferably, the angle is as steep as possible, for example more than 80°, and most preferably approximately perpendicular in relation to plane of the substrate front. Even overhanging angles of more than 90° are possible so that the flank undercuts the substrate rear.

Preferably, the flank is formed by means of a laser. In this process, for example, in the first region, by means of radiation with a high-energy laser of suitable emission wavelength, substrate material can be removed so that the first region is closer to the substrate front than the second region, i.e. so that the substrate in the first region is thinner than that in the second region. At the transition from the first, lower, deep-groove-shaped region to the second, higher, raised region, the flank is thus produced. When the two regions, as described above, are interdigitated, i.e. nestled in a comb-like manner, the flank extends along the entire comb structure.

Depositing a metal layer preferably takes place on the entire substrate rear. There is no need for any masking, for example by means of photolithography, of individual regions of the substrate rear. Possibly some regions of the substrate rear, which are used for holding the substrate during the depositing process, remain free of the metal layer. Preferably, aluminium is used for the metal layer.

After the metal layer has been deposited, again at least in some regions, an etching barrier layer is deposited on said metal layer. The etching barrier layer thus covers the metal layer at least partially.

According to the invention, the etching barrier layer is essentially resistant to etchant that etches the metal layer. This means that etchant, for example a liquid etching solution or a reactive gas that severely attacks the metal layer, does not etch the etching barrier layer, or etches it only slightly. For example, the etching rate of the etchant in relation to the metal layer is to be much greater, for example by a factor of ten, than it is in relation to the etching barrier layer. For example, metals such as silver or copper can be used for the etching barrier layer, as can dielectric materials such as silicon oxide or silicon nitride.

In a subsequent process step the substrate rear, with the metal layer on it and with the etching barrier layer that covers said metal layer, is exposed to the etchant. In the regions covered by the etching barrier layer the metal layer is not attacked or only slightly attacked by the etchant. On the other hand in the flank region, in which, due to its inclined arrangement in relation to the first region and the second region on the substrate rear the etching barrier layer is only very thin, comprises holes, or has not formed at all, the etchant can directly attack the metal layer. In addition, the etching barrier layer is undercut by etching, or, without the underlying metal layer that has been edged away, is insufficiently stable and is finally preferably completely removed in the etching step. As a result, the metal layer in the first region is no longer electrically connected to the metal layer in the second region.

Preferably, a metal is used for the etching barrier layer, which metal can be soldered, for example silver or copper. In this document the notion “can be soldered” or “solderable” means that a conventional cable or a contact strip can be soldered to the etching barrier layer, which cable or contact strip can, for example, be used to interconnect the solar cells. For this purpose, simple and economical soldering methods are to be able to be used, without the need for special solder or special tools as they are, for example, required for soldering aluminium or titanium or compounds of such metals. For example, the etching barrier layer is to be solderable by means of conventional silver solder and conventional soldering irons.

With the use of a solderable etching barrier layer a situation is achieved wherein, after etching, the etching barrier layer need not be removed from the cell surface in order to solder a contact strip to the underlying metal layer during interconnection of solar cells.

Preferably, the metal layer and/or the etching barrier layer are/is directionally deposited essentially perpendicularly in relation to the first region and the second region. Such depositing can take place by vapour depositing, e.g. thermally or by means of an electron beam, or by sputtering. In this process, the directional nature of depositing results from the geometry in which the semiconductor substrates during depositing are arranged in relation to the source from which the material of the respective layer emanates. On average, the material particles from the source should impinge on the first region and the second region approximately perpendicularly, for example at an angle of 90°±20°.

In this way a situation is achieved in which on the first region and on the second region considerably more metal is deposited than is the case on the flank that separates these regions, because the flank has an acute angle of preferably less than 30° in relation to the direction of propagation of the material particles. The etching barrier layer is deposited only very thinly so that in the first region and in the second region its thickness is less than 5 μm, preferably less than 2 μm, more preferably less than 500 nm. In the inclined flank region, the etching barrier layer is then so thin or has a porous structure that in those locations it can no longer effectively act as an etching barrier.

In an embodiment of the invention the above-described method is used in the production of so-called emitter-wrap-through (EWT) solar cells. In this arrangement a region that forms the rear emitter region of the solar cell is electrically conducted to an emitter on the front of the solar cell by way of connecting channels that also comprise emitter doping. Preferably, in this arrangement the surfaces of the entire semiconductor substrate are provided with a dielectric layer, for example a thermal oxide with a thickness in excess of 100 nm, and this oxide is subsequently, in a wet-chemical process, selectively removed from the substrate front. On the substrate rear, in what will later be the emitter regions, the oxide together with the underlying substrate material is removed, by means of a laser, to a depth that is sufficient for a flank to form that is at least a few micrometers in height. At the same time the connecting channels to the substrate front are made using the laser. During subsequent emitter diffusion the remaining dielectric layer serves as a diffusion barrier to the underlying regions so that an emitter is diffused only in the previously exposed regions of the front and of the rear, as well as in the connecting channels.

The use of the method according to the invention to produce EWT solar cells is associated with an advantage in that in a common process step, by means of a high-energy laser, a overlying diffusion barrier layer can be removed from the rear emitter regions, and the connecting channels to the front emitter can be formed.

In a further embodiment of the method according to the invention, several flanks are designed between the first and the second region. This can, for example, take place in that, with a laser, deep grooves are formed between the first and the second region, which deep grooves comprise additional flanks that are arranged so as to be approximately perpendicular. This may ensure even more reliable electrical separation of the first region from the second region.

According to a second aspect of the present invention, a solar cell is proposed which comprises: a semiconductor substrate with a substrate front and a substrate rear; a base region of a first doping type on the substrate rear, an emitter region of a second doping type on the substrate rear, and an emitter region of the second doping type on the substrate front, wherein the base region and the emitter region on the substrate rear are separated by a flank region that is arranged so as to be inclined in relation to said regions; a base contact, which electrically contacts the base region at least in partial regions, and an emitter contact, which electrically contacts the emitter region on the substrate rear at least in partial regions, wherein the base contact and the emitter contact each comprises a first metal layer that contacts the semiconductor substrate, which metal layer extends so as to be essentially parallel in relation to the substrate front, wherein the flank region does not comprise a metal layer, so that the emitter contact and the base contact are electrically separated.

The solar cell can, in particular, comprise the characteristics as can be provided by the above-described method according to the invention.

In other words the function principle of the invention can be described in brief as follows:

The elegant and new principle of contact separation is based on vapour depositing or sputtering a thin aluminium layer for contacting the n-doped and p-doped cell regions. A silver layer or copper layer subsequently vapour deposited or sputtered on the aforesaid ensures the solderability of the solar cell and at the same time is used as an etching barrier against attack by an etching solution in one of the following process steps.

On the flank-like structures at the transition between the raised and the depressed regions of the solar cell rear, due to the metallising process, the last-deposited layer, which is used as an etching barrier, is not completely etch-proof, thus making it possible to be attacked by an etching solution, which in a defined manner removes the first-deposited metal layer from these regions. In this process the etching barrier itself is undercut by etching, and any residues of said etching barrier can be quickly removed, in a second etching step, which second step attacks the etching barrier itself, particularly from the region of the flank-like structures, which region has been undercut by etching.

Amplification of this effect is for the first time achieved by using two or more closely spaced deep grooves (as described further below with reference to FIG. 3). As a result of the effect of undercutting by etching, the entire metallisation of the narrow raised region between the closely spaced deep grooves is removed in a defined manner.

The narrow deep grooves themselves can be produced quickly and economically with the use of laser processes.

Further characteristics and advantages of the invention are set out in the following detailed description of preferred exemplary embodiments in the context of the accompanying drawings.

### BRIEF DESCRIPTION OF THE DRAWINGS

FIG. 1 diagrammatically shows a method-related sequence according to the invention.

FIG. 2 diagrammatically shows a section view of a solar cell according to the invention according to a first embodiment.

FIG. 3 diagrammatically shows a section view of a solar cell according to the invention according to a second embodiment.

FIG. 4 diagrammatically shows a section view of a solar cell according to the invention according to a third embodiment.

### DESCRIPTION OF PREFERRED EXEMPLARY EMBODIMENTS

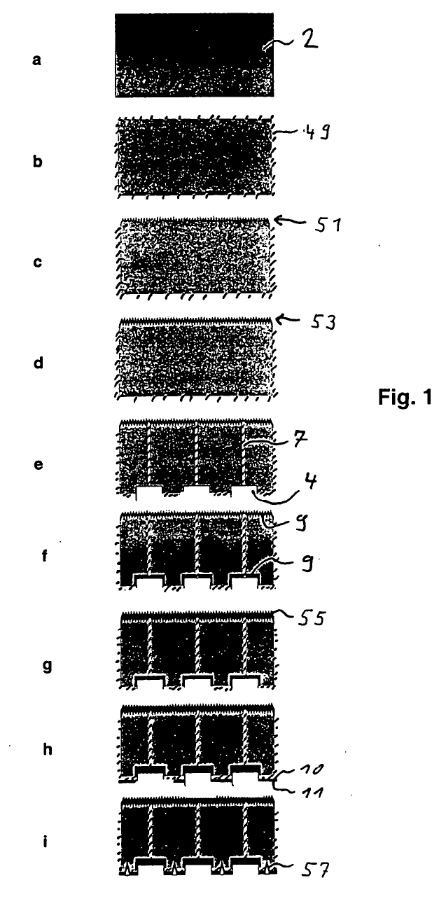

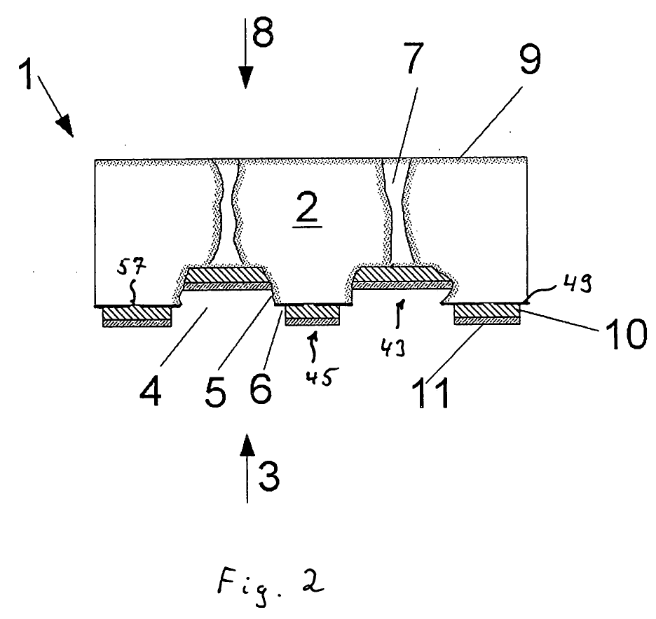

With reference to FIG. 1, first an embodiment of a production method according to the invention is described, as can be applied in a similar way in the production of the solar cell 1 according to the invention, which solar cell is shown in FIG. 2.

First (in step a) a silicon wafer 2 is subjected to tenside cleaning in a heated ultrasonic bath. Subsequently, the damage caused during sawing of the wafer is edged off in heated KOH, wherein approximately the outermost 10 μm of the wafer is removed. Subsequently, the wafer is subjected to so-called RCA cleaning, wherein the wafer surface is oxidised by a sequence of NH₄OH-, HF-, HCl- and HF-rinses, with the oxide subsequently being etched off.

Next (in step b) the entire wafer surface is oxidised in an N₂/O₂ atmosphere at approximately 1050° C. to an oxide thickness of approximately 250 nm.

This oxide layer 49 is then (in step c) removed from what will later be the cell front 8 by means of a horizontal etching process in an HF bath, and on the exposed substrate front a surface texture 51 is produced by a dip in heated texture solution, e.g. a solution of KOH and IPA (isopropyl alcohol).

Subsequently (in step d) the textured substrate front is protected by depositing an SiN-layer 53 that is approximately 60 nm in thickness.

In a subsequent step (e), by means of a high-energy laser, parts of the substrate rear 3 and of the oxide layer 49 situated thereon are removed and in this way first deep-groove-shaped regions 4 are produced. The first regions 4 are separated from second, raised regions 6 by means of flanks 5 (FIG. 2). In this arrangement the deep-groove index, i.e. the distance from the middle of a first region to the middle of an adjacent first region, is 2.5 mm, while the deep-groove width is 1.25 mm.

In the same method-related step (e), by means of the laser, connecting channels 7 leading from the first regions 4 to the substrate front 8 are produced.

After renewed cleaning of the wafer with water-deluted HCl (and possibly ultrasound) as well as optionally NH4OH, the damage caused during laser treatment is etched off to a depth of approximately 10 μm in heated KOH. This is followed by further cleaning in hot HNO₃ and subsequently in cold HF. Thereafter (in step f) on the entire substrate surface that is not covered by oxide 49, an emitter is diffused in, in a tube furnace, by means of POCl₃ diffusion. The layer resistivity of the emitter is set to approximately 40 ohm/square.

There is renewed RCA cleaning before (in step g) a double layer 55 comprising SiN is deposited on the substrate front. The first SiN layer is used for surface passivation and measures approximately 10 nm in thickness. The second layer is used as an antireflex layer and at a refractive index of, for example 2.05, measures approximately 100 nm in thickness.

After shortened RCA cleaning, in which the final HF dip is left out, in an N₂/O₂ atmosphere at 500° C. a tunnel oxide that measures only 1.5 nm in thickness is produced.

Subsequently (in step h) the rear is metallised. To this effect, by means of an electron beam gun, first a metal layer 10 of aluminium, which metal layer measures approximately 15 μm in thickness, is vapour deposited. In this arrangement the thickness of the aluminium layer relates to the first and second regions 4, 6 of the substrate rear, which regions 4, 6 are aligned so as to be approximately perpendicular in relation to the direction of propagation of the aluminium vapour. Corresponding to the angle of inclination (for example in a cosine dependence) less aluminium is deposited on the flanks 5 that are aligned so as to be inclined in relation to the above. Subsequently, also by means of the electron beam gun, a metal layer 11, which measures approximately 2 μm in thickness, of silver is deposited over the aluminium.

In a subsequent selective etching step the silver layer 11 is used as an etching barrier layer. In this process HCl is used as an etchant, which severely attacks aluminium while hardly etching silver. In this process, as a result of the silver layer being too thin or being porous in the flank region, the aluminium layer is etched away in this region. In the first and second regions, which are tightly protected by silver, the etching solution does not contact the aluminium layer so that in these regions said aluminium layer remains largely intact.

Finally (in step i) the base contacts 10 are driven through the underlying oxide 49 by means of a laser so as to electrically contact the base regions of the solar cell by means of local contacts 57. This process is known as an LFC process (laser fired contacts, see DE 100 46 170 A1). Finally, this is followed by tempering for 1 to 3 minutes at approximately 330° C.

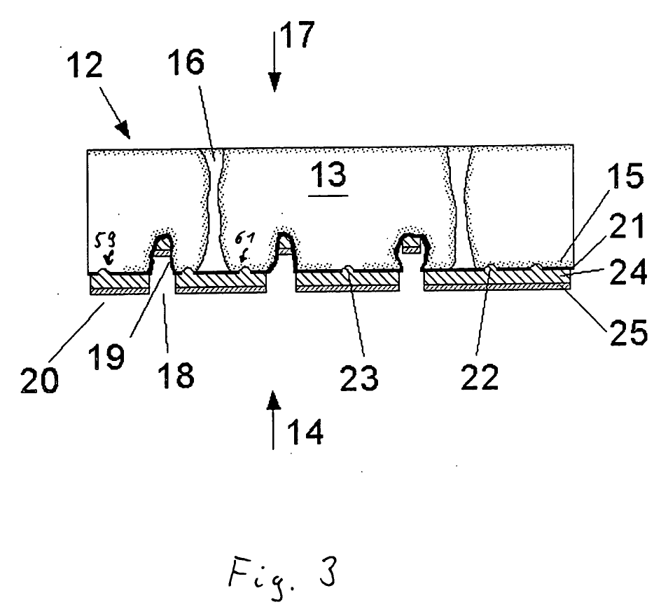

With reference to FIG. 3, a further embodiment of a solar cell according to the invention is explained.

As described above, a solar cell (12) with a semiconductor substrate (13) is proposed, whose electrical contacting takes place on the semiconductor substrate rear (14). The semiconductor substrate rear comprises locally n-doped regions (15) that are connected to the semiconductor substrate front (17) by small holes (16). The semiconductor substrate front as well as the small holes also comprise the n-doped layer. The semiconductor substrate itself is p-doped.

The semiconductor rear comprises locally narrow deep-groove-shaped regions (18), which are delimited to the wide raised regions (20) of the semiconductor rear by means of flank-like structures (19).

First, the semiconductor substrate rear comprises a dielectric layer (21) over its entire area. The dielectric layer locally comprises openings (22) to the n-doped region and openings (23) to the p-doped region.

Over its entire area, the dielectric layer, including the open regions (22, 23), is coated with an electrically conductive material (24), preferably aluminium. Coating preferably takes place by vapour depositing or sputtering. Subsequently, a further electrically conductive and solderable layer (25), preferably of silver or copper, is deposited on the aforesaid coating.

To prevent the two conductive materials (24) and (25) from short circuiting the solar cell, the raised regions (20) of the semiconductor substrate rear are separated as a result of being attacked by an etching solution or by a sequence of wet-chemical etching steps on the flank-like structures (19).

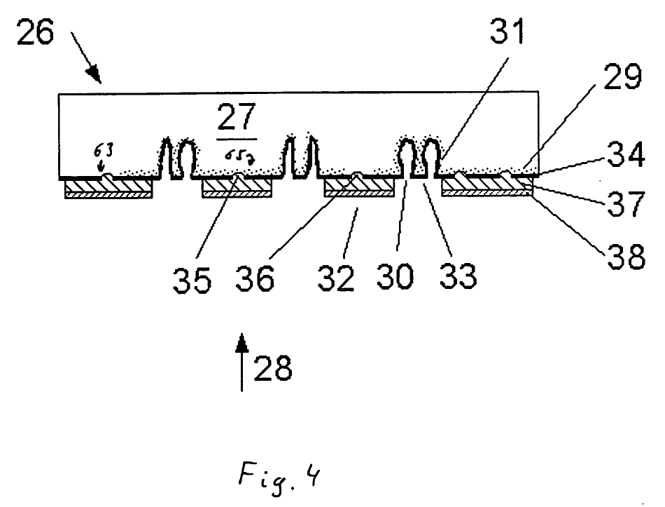

With reference to FIG. 4, a further exemplary embodiment of a solar cell according to the invention is explained.

As described above, a solar cell (26) with a semiconductor substrate (27) is proposed, with the electrical contacting of said semiconductor substrate (27) taking place on the semiconductor substrate rear (28). The semiconductor substrate rear comprises locally n-doped regions (29), with the semiconductor substrate itself being p-doped.

The semiconductor substrate rear comprises locally narrow deep-groove-shaped regions (30), which are delimited to the wide raised regions (32) of the semiconductor rear by flank-like structures (31). In each case, two deep-groove-shaped regions (30) are closely spaced and are delimited from each other by a narrow raised region (33).

The rear of the semiconductor substrate first comprises a dielectric layer (34) over its entire surface. The dielectric layer locally comprises openings (35) to the n-doped region, and openings (36) to the p-doped region.

The dielectric layer including the opened regions (35, 36) is first coated over its entire area with an electrically conductive material (37), preferably aluminium. Coating preferably takes place by vapour depositing or sputtering. Subsequently, a further, electrically conductive and solderable, layer (38), preferably of silver or copper, is deposited on this layer.

To prevent the two conductive materials (37) and (38) from short circuiting the solar cell, the wide raised regions (32) of the semiconductor substrate rear are separated on the flank-like structures (31) and on the narrow raised regions (33) preferably by means of an attack by an etching solution or of a sequence of wet-chemical etching steps.

The embodiment shown in FIG. 4 primarily serves to show the double deep grooves (30), which contribute to improved electrical separation between the emitter contacts and the base contacts. For the sake of clarity, an optional emitter on the substrate front and doped connecting channels between rear and front emitter regions have been left out in the figure.

As an alternative, embodiments of the solar cell according to the invention can be described as follows:

A solar cell comprising a semiconductor substrate, preferably silicon, whose electrical contacting takes place on the semiconductor substrate rear, characterised in that the cell rear comprises locally deep-groove-shaped regions that are separated from the raised regions by flank-like regions.

The solar cell according to any one of the preceding embodiments, characterised in that either the deep-groove-shaped regions of the semiconductor substrate rear or at least parts of the raised regions of the semiconductor substrate rear are connected to the semiconductor substrate front by small holes.

The solar cell according to any one of the preceding embodiments, characterised in that the entire area or almost the entire area of the cell rear is first coated with a layer sequence comprising at least two electrically conductive materials.

The solar cell according to any one of the preceding embodiments, characterised in that the first-applied layer comprises aluminium, and at least one subsequently applied layer is solderable.

The solar cell according to any one of the preceding embodiments, characterised in that at least one of the applied layers is deposited by vapour depositing or sputtering.

The solar cell according to any one of the preceding embodiments, characterised in that separation of the electrically conductive layer of the cell rear into two or more regions takes place by means of the attack by an etching solution or a sequence of several wet-chemical etching steps in the region of the flank-like regions.

The solar cell according to any one of the preceding embodiments, characterised in that in each case two or more deep-groove-shaped regions are situated closely spaced and are delimited from each other by a narrow raised region.

The solar cell according to any one of the preceding embodiments, characterised in that separation of the electrically conductive layer of the rear surface of the cell into two or more regions takes place as a result of an attack by an etching solution or as a result of several wet-chemical etching steps in the region of the flank-like regions and of the narrow raised region between the deep-groove-shaped regions that are situated closely spaced.

In summary, the invention can also be described as follows:

A solar cell (1) with a semiconductor substrate (2) is proposed, with electrical contacting of said semiconductor substrate (2) taking place on the rear (3) of the semiconductor substrate. The rear of the semiconductor substrate comprises locally deep-groove-shaped regions (4), which are delimited to the raised regions (6) of the rear of the semiconductor substrate by flank-like structures (5).

The deep-groove-shaped regions are connected to the front (8) of the semiconductor substrate by small holes (7). The front of the semiconductor substrate as well as the small holes and the deep-groove-shaped regions including the flank-like structures comprise an n-doped layer. The semiconductor substrate itself is p-doped.

The entire surface of the rear of the semiconductor substrate is at first coated with an electrically conductive material (10). Coating preferably takes place by vapour depositing or sputtering. Subsequently, a further, electrically conductive and solderable, layer (11) is deposited on said layer.

To prevent the two conductive materials (10) and (11) from short circuiting the solar cell, the deep-groove-shaped regions (4) are separated from the raised regions (6) of the rear of the semiconductor substrate by means of an attack by an etching solution or of a sequence of wet-chemical etching steps on the flank-like structures (5).

The solar cell according to the invention, and the production process according to the invention have been described in the above embodiments merely by way of examples. Changes and modifications, as are within the scope of the enclosed claims, are obvious to the average person skilled in the art.

With the solar cell presented, which is also referred to as a RISE-EWT cell (rear interdigitated single evaporation-emitter wrap through), among other things the following advantages are achieved: among other things the cell is highly efficient due to intermeshing contact grids for the emitter and the base only on the rear surface of the cell. The high-grade electrical contacts are generated by vacuum deposition. A collecting pn-junction is arranged both on the front and on the rear of the cell. The cell is protected by excellent surface passivation based on silicon nitride and thermally grown silicon dioxide.

The production process is characterised by its simplicity and by industrial implementability, because no masking steps and lithography steps are involved. Furthermore, processing takes place in a “gentle” manner, i.e. laser processing is used instead of mechanical processing steps; and vacuum depositing is used for contact formation instead of screen printing. Consequently, the method is suitable in particular for sensitive thin silicon wafers. Consequently, the method has great potential for cost reduction.

1. A method for producing a solar cell, comprising the following steps:
providing a semiconductor substrate with a substrate front and a substrate rear;
forming a first and a second region on the substrate rear, wherein in each case the regions are essentially parallel in relation to the substrate front, and forming an inclined flank that separates the first region from the second region;
depositing a metal layer at least on partial regions of the substrate rear;
depositing an etching barrier layer at least on partial regions of the first metal layer, wherein the etching barrier layer is essentially resistant to an etchant that etches the metal layer;
etching the metal layer at least in partial regions, wherein the metal layer on the inclined flank is essentially removed.

2. The method of claim 1, wherein the etching barrier layer is solderable.

3. The method according to claim 1, wherein the etching barrier layer comprises silver or copper, or both silver and copper.

4. The method according to claim 1, wherein the forming of the inclined flank is such that the inclined flank forms an angle of at least 60° in relation to the substrate front.

5. The method according to claim 1, wherein depositing the etching barrier layer takes place directionally in a direction that is essentially perpendicular in relation to the substrate front.

6. The method according to claim 1, wherein depositing the etching barrier layer takes place by vapour depositing or by sputtering.

7. The method according to claim 1, wherein forming the flank takes place by means of a laser.

8. The method according to claim 1, wherein forming the first region takes place by means of a laser.

9. The method according to claim 1, wherein forming the first region takes place such that the first region is closer to the substrate front than is the second region.

10. The method according to claim 1, further comprising the step of forming a dielectric layer on the substrate rear prior to forming the first and the second region, wherein during forming of the first region the dielectric layer is locally removed in the first region.

11. The method according to claim 1, further comprising the step of forming a doped emitter layer both on the substrate front and in the first region of the substrate rear.

12. The method according to claim 1, further comprising the step of forming emitter-doped connecting channels which connect the first region of the substrate rear to the substrate front.

13. The method according to claim 1, wherein several flanks are formed between the first region and the second region.

14. A solar cell comprising:
a semiconductor substrate with a substrate front and a substrate rear;
a base region of a first doping type on the substrate rear, an emitter region of a second doping type on the substrate rear, and an emitter region of the second doping type on the substrate front, wherein the base region and the emitter region on the substrate rear are separated by a flank region that is arranged so as to be inclined in relation to said regions;
a base contact, which electrically contacts the base region at least in partial regions, and an emitter contact, which electrically contacts the emitter region on the substrate rear at least in partial regions, wherein the base contact and the emitter contact each comprises a first metal layer that contacts the semiconductor substrate, which metal layer extends so as to be essentially parallel in relation to the substrate front, wherein the flank region does not comprise a metal layer, so that the emitter contact and the base contact are electrically separated.

15. The solar cell according to claim 14, further comprising a solderable second metal layer which at least partly covers the first metal layer.

16. The solar cell according to claim 15, wherein the second metal layer comprises silver or copper, or both silver and copper.

17. The solar cell according to claim 14, wherein the first metal layer comprises aluminium.

18. The solar cell according to claim 14, wherein the flank region forms an angle of more than 60° in relation to the substrate front.

19. The solar cell according to claim 14, wherein the emitter region of the substrate rear is nearer the substrate front than is the base region.

20. The solar cell according to claim 14, wherein the emitter region on the substrate rear is connected to the emitter region on the substrate front by way of emitter-doped connecting channels.

21. The solar cell according to claim 14, further comprising a dielectric layer between the base region and the base contact, wherein the base contact locally contacts the base region through openings in the dielectric layer.

22. The solar cell according to claim 14, wherein the base region is separated from the emitter region of the substrate rear by at least one deep groove, which comprises flank regions.
